(19) United States
(12) Patent Application Publication
(10) Pub. No.: US 2026/0215159 A1
(43) Pub. Date: Jul. 23, 2026

(54) SIGNAL PROCESSING METHOD, SIGNAL PROCESSING SYSTEM, AND SIGNAL PROCESSING PROGRAM

(71) Applicant: TOPOLOGIC INC., Tokyo (JP)

(72) Inventor: Arata TAKAHASHI, Tokyo (JP)

(21) Appl. No.: 19/143,301

(22) PCT Filed: Dec. 21, 2023
(86) PCT No.: PCT/JP2023/045898

§ 371 Date: Jun. 25, 2025

(30) Foreign Application Priority Data
Dec. 27, 2022 (JP) 2022-210991

(51) Int. Cl. H10N 15/00; G01K 7/02

(52) U.S. Cl. CPC H10N 15/00; G01K 7/021

(57) ABSTRACT

A signal processing method in a measuring system is provided. The measurement system in this signal processing method is provided with a thermoelectric conversion unit. The thermoelectric conversion unit is configured to convert a temperature gradient, which is caused by heat exchange with a measurement target, to an electric signal on the basis of an anomalous Nernst effect. The signal processing method includes the following steps. In a modulation step, a modulation including a prescribed modulation frequency is introduced to an electric signal output by the thermoelectric conversion unit to generate a modulation signal. The modulation frequency is a different frequency from the frequency band of the thermoelectric conversion unit. In an extraction step, a signal of a component of the modulation frequency is extracted from the modulation signal.

### CROSS REFERENCE TO RELATED APPLICATIONS

This application is a 371 U.S. National Phase of International Application No. PCT/JP2023/045898, filed on Dec. 21, 2023, which claims priority to Japanese Patent Application No. 2022-210991, filed Dec. 27, 2022. The entire disclosures of the above applications are incorporated herein by reference.

### BACKGROUND

### Technical Field

The present invention relates to a signal processing method, signal processing system, and signal processing program.

### Related Art

Japanese Unexamined Patent Application Publication No. 2019-086490 discloses a technology related to a humidity detection device that is more responsive and less susceptible to condensation than conventional humidity detection devices.

The humidity detection device described in Japanese Unexamined Patent Application Publication No. 2019-086490 includes a heat flow sensor disposed on a side wall surface of a gas-liquid separator that forms an internal space through which a fuel off-gas circulates and a hydrophilic sheet for forming a liquid film on a surface of the heat flow sensor. The humidity detection device includes a detection unit that detects the humidity of the fuel off-gas on the basis of an output signal from the heat flow sensor.

A signal indicating a heat gradient detected by a heat flow sensor or the like is weak compared to a signal directly indicating a temperature detected by a thermometer or the like.

For this reason, there is still room for improvement in the use of such a heat gradient-related signal in various terms such as the effect of noise and the size.

### SUMMARY

According to one aspect of the present invention, a signal processing method in a measuring system is provided. The measuring system that performs this signal processing method includes a thermoelectric conversion unit. The thermoelectric conversion unit is configured to convert a temperature gradient generated by heat exchange with an object to be measured into an electrical signal on the basis of the anomalous Nernst effect. The signal processing method includes the following steps. A modulation step is a step of generating a modulated signal by introducing a modulation including a predetermined modulation frequency into the electrical signal outputted from the thermoelectric conversion unit. The modulation frequency is a frequency different from a frequency band of the thermoelectric conversion unit. An extraction step is a step of extracting a signal of a component of the modulation frequency from the modulated signal.

Such a configuration can provide a method or the like that allows the signal indicating the detection result of the temperature gradient to be more suitably used.

### BRIEF DESCRIPTION OF THE DRAWINGS

FIG. 1 is a diagram showing an example configuration of a measuring system 1a.

FIG. 2 is a block diagram showing the hardware configuration of a signal processing device 4.

FIG. 3 is an activity diagram showing an example of signal processing performed by the measuring system 1a.

FIG. 4 is a diagram showing changes over time in a total electromotive force V1 outputted from one heat flow sensor 2.

FIG. 5 is a diagram showing changes over time in a modulated signal V2.

FIG. 6 is a diagram showing an example of the frequency spectrum of the modulated signal V2 shown in FIG. 5.

FIG. 7 is a diagram showing an example configuration of a measuring system 1b.

FIG. 8 is a diagram showing changes over time in a first total electromotive force V1a and a second total electromotive force V1b.

FIG. 9 is a diagram showing changes over time in a first modulated signal V2a and a second modulated signal V2b.

FIG. 10 is a diagram showing an example of the frequency spectrum of a calculated electrical signal V4 obtained by subtracting the first modulated signal V2a and second modulated signal V2b shown in FIG. 9 from each other using a calculation circuit 315.

FIG. 11 is a diagram showing an example configuration of a measuring system 1c.

FIG. 12 is a plan view from a z-axis direction of a heat flow sensor 2 in which a magnetic field application unit 53 is incorporated.

FIG. 13 is a plan view from the z-axis direction of the magnetic field application unit 53 incorporated in the heat flow sensor 2.

FIG. 14 is a cross-sectional view of a surface including the z-axis direction of the heat flow sensor 2 shown in FIG. 12.

FIG. 15 is an activity diagram showing an example of signal processing performed by the measuring system 1c.

FIG. 16 is a diagram showing another example of the magnetic field application unit 53.

### DETAILED DESCRIPTION

Now, a preferred embodiment of the present disclosure will be described in detail with reference to the accompanying drawings. In the present specification and drawings, components having substantially the same functional configuration are given the same reference signs and will not be repeatedly described.

A program to implement software in the present embodiment may be provided as a computer-readable non-transitory storage medium, or may be provided by download from an external server. The program may also be provided such that it is run on an external computer and its functions are implemented on a client terminal (so-called cloud computing).

The term “unit” in the present embodiment includes, for example, a combination of hardware resources implemented by a circuit in a broad sense and software information processing that can be specifically performed by the hardware resources. Various types of information handled in the present embodiment are represented by, for example, the physical values of signal values representing voltages or currents, high or low signal values as binary bit sets consisting of 0s or 1s, or quantum superpositions (so-called qubits) and can be transmitted and subjected to a calculation on a circuit in a broad sense.

The term “circuit in a broad sense” refers to a circuit implemented by combining at least a circuit, circuitry, a processor, memory, and the like appropriately.

Specifically, the term “circuit in a broad sense” includes an application-specific integrated circuit (ASIC), programmable logic devices (e.g., a simple programmable logic device (SPLD), a complex programmable logic device (CPLD), a field programmable gate array (FPGA)), and the like.

### 1. Overview of Present Embodiment

Conventional heat flow sensors tend to be subjected to low-frequency noise due to their high impedance and therefore have difficulty in making correct measurements. For example, a device such as a heat flow sensor based on the anomalous Nernst effect outputs a signal corresponding to the magnetization of the sensor. For this reason, when the magnetization direction, intensity, or the like of the sensor is changed by, for example, a disturbing magnetic field (i.e., magnetic field noise), the sensitivity of the sensor would be changed. Thus, in an environment with a strong disturbing magnetic field, the measurement accuracy of the sensor would be reduced. The sensor also tends to be affected by electrical noise. In view of the foregoing, there is room for improving the accuracy of measurement of a heat flow. Use of a shield is also conceivable as a conventional method, but this method tends to increase the cost, as well as increase the size of the structure.

For these reasons, a device according to the present embodiment, a system using the device, and a method related to these separate noise components and signal components, for example, by performing electrical and/or magnetic chopping. By separating the noise components by frequency, the measurement accuracy is improved.

A heat flow sensor (an example of a device) according to the present embodiment is preferably a thin film-type heat flow sensor based on the anomalous Nernst effect in terms of the responsiveness. The elements (i.e., the thermoelectric conversion elements) of the heat flow sensor (i.e., a thermoelectric conversion device) may be made of a compound that exhibits anomalous Nernst effects. For example, the elements may be made of a topological ferromagnetic material or topological antiferromagnetic material called Weyl semimetal, a ferrimagnetic material, or a combination thereof. The topological ferromagnetic material may be a metal with a composition Co₂TX (where X represents any one of Si, Ge, Sn, Al, and Ga), such as Co₂MnGa, or may be an alloy of a known topological ferromagnetic material, such as a metal with a composition formula Fₑ3X (where X represents a typical element such as Al or Ga, or a transition element) (a stoichiometric or off-stoichiometric composition). The topological antiferromagnetic material may be a known topological antiferromagnetic material, such as Mn₃X (where X represents one or more elements selected from Sn, Ge, Ga, Pt, Ir, and Rh, or a compound of these). The alloy containing the topological ferromagnetic material or topological antiferromagnetic material does not necessarily have to have a stoichiometric composition ratio as described above. The alloy may have any composition ratio as long as it has a partially stoichiometric structure. The compound constituting the elements may consist of, for example, an alloy containing a transition metal, and the alloy may be a compound that has a crystal structure with Kagome lattice planes made of a transition metal and exhibits the anomalous Nernst effect. The ferrimagnetic material may be of any type as long as it generates the anomalous Nernst effect. The elements may have any structure, and known structures can be used. The elements according to the present embodiment may be formed by sputtering, evaporation, MBE, plating, sintering, printing, pasting, or the like. The heat flow sensor according to the present embodiment may be configured not only to measure heat, but also to detect light, a chemical, or the like. For convenience's sake, the thermoelectric conversion elements may be hereinafter referred to as the thermoelectric conversion units.

A chopping circuit is disposed between the output unit (the ends of the elements) of the heat flow sensor and an amplifier/AD conversion circuit. Thus, the band of noise is shifted from the band of the sensor, resulting in cancellation of electromagnetic field noise. Moreover, sampling is performed in different chopping phases, and signal processing is performed using, for example, differential processing, a low-pass filter, a high-pass/band-pass filter, or the like. These allow information on only the signal to be acquired. The signal processing itself may be performed in an analog or digital form, and an amplifier may be used midway.

When magnetic field noise (disturbing magnetic field) is applied to the heat flow sensor, the magnetization of the elements would vary, resulting in a variation in a coefficient a that influences the signal output of the heat flow sensor. Thus, a heat flow value Q also would vary.

For this reason, a coil may be disposed near the heat flow sensor (device) so that an external magnetic field can be applied to the heat flow sensor. By measuring the heat flow while applying an external magnetic field to the heat flow sensor, the effect of a disturbing magnetic field on the magnetic material is suppressed. Thus, the sensitivity of the sensor is stabilized. Specifically, by applying a relatively large magnetic field Hb as an external magnetic field to the heat flow sensor, the magnetization M is stably obtained and the sensitivity is kept high.

Moreover, by changing the direction of application of the magnetic field by the coil and using differential processing, low-pass filter, or high-pass/band-pass filter, noise is reduced. The signal processing itself may be performed in an analog or digital form, and an amplifier may be used midway.

A modification of the present embodiment will be described below. A coil may be layered on the sensor rather than disposing it outside the sensor. By making the direction of the magnetic field of the coil an in-plane direction of the sensor, the magnetic field can be strongly applied to the sensor. An insulating layer (bonding layer) may be disposed between the sensor and the coil.

Even if the coil is small, it can generate a larger magnetic field by increasing the number of turns of the coil.

A heat sink may be disposed below the sensor and coil. Thus, the accuracy of measurement of the amount of heat Q is further improved.

Another modification of the present embodiment will be described below. The coil disposed outside the sensor may be an air-core coil. Such a coil can generate a strong magnetic field in the sensor. A soft magnetic material may be disposed inside the air-core coil. The coil may be disposed on one or both sides of the sensor.

By inputting a periodic wave, particularly, a sinusoidal wave to the outside coil, an external magnetic field based on such a wave is outputted. A combination of such an input signal, the output signal of the sensor, and the large external magnetic field Hb stabilizes the magnetic field and keeps the sensitivity high. The signal processing itself may be performed in an analog or digital form, and there is no problem in using an amplifier midway. Preferably, the magnetic field applied from the coil is that having good linearity and optimal size. Such a circuit may have a heterodyne configuration. Examples of the above aspects of the present embodiment will be described in detail.

### 2. Measuring System According to First Embodiment

This section describes a measuring system 1a according to a first embodiment (hereinafter simply referred to as the measuring system 1a).

### 2.1.1 Example Configuration of First Embodiment

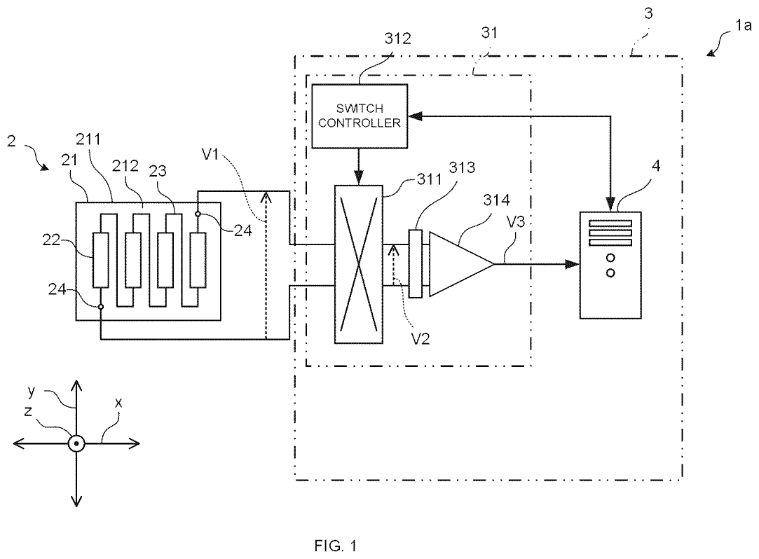

FIG. 1 is a diagram showing an example configuration of the measuring system 1a. As shown in FIG. 1, the measuring system 1a includes at least one heat flow sensor 2 and a signal processing system 3.

### Heat Flow Sensor 2

The heat flow sensor 2 is disposed to exchange heat with an object to be measured (not shown). The heat flow sensor 2 includes a substrate 21 as an insulator, at least one (in the present embodiment, multiple) thermoelectric conversion unit 22, wiring 23, and an output unit 24.

The substrate 21 is configured to contact the object to be measured (not shown). The substrate 21 has a connecting surface 211 as a second surface and a measuring surface 212 as a first surface. The connecting surface 211 is configured to contact the object to be measured. The measuring surface 212 is positioned opposite to the connecting surface 211 in the thickness direction of the substrate 21. For convenience's sake, the thickness direction of the substrate 21 may be hereinafter referred to as a z-axis direction.

The thermoelectric conversion unit 22 is configured to convert a temperature gradient generated by heat exchange with the object to be measured into an electrical signal on the basis of the anomalous Nernst effect. The multiple thermoelectric conversion units 22 are disposed (e.g., layered) on the measuring surface 212 of the substrate 21 and configured to exchange heat with the object to be measured through the substrate 21. Thus, in each of the thermoelectric conversion units 22, a temperature gradient based on the heat flow from the measuring surface 212 occurs along the normal direction of the measuring surface 212. The thermoelectric conversion units 22 are also each spontaneously magnetized in a direction different from the temperature gradient and thus configured to generate an electromotive force in an in-plane direction on the basis of the temperature gradient. For example, the normal direction of the measuring surface 212 coincides with the z-axis direction. The thermoelectric conversion units 22 are formed as thin films. Each thermoelectric conversion unit 22 may include a magnetic domain configured to be magnetized along an in-plane direction of the thin film. The thermoelectric conversion units 22 may be formed in bulk. The in-plane directions are perpendicular to the normal direction of the measuring surface 212. In the present embodiment, the in-plane directions include an x-axis direction and a y-axis direction. The y-axis direction is the direction in which the thermoelectric conversion units 22 extend, and the x-axis direction is defined as a direction perpendicular to the y-axis direction. In the present embodiment, the thermoelectric conversion units 22 are configured to be magnetized along the x-axis direction, which is one of the in-plane directions.

The wiring 23 connects the multiple thermoelectric conversion units 22 in series such that the polarities thereof are aligned.

The output unit 24 is a terminal configured to output the total value of electromotive forces outputted from all the multiple thermoelectric conversion units 22. The output unit 24 does not have to be mounted as an actual connecting terminal but may be a virtual terminal connected to an external element. In the present embodiment, the heat flow sensor 2 includes a pair of output units 24, and the pair of output units 24 output a total electromotive force V1, which is the total value of the electromotive forces of the thermoelectric conversion units 22. In the present embodiment, the heat flow sensor 2 outputs the total electromotive force V1 based on the heat flow associated with the temperature gradient from the output units 24. Ideally, V1=k×M×Q (where k represents a proportional constant, M represents the magnetization of the thermoelectric conversion units 22, and Q represents the heat flow). Actually, V1=k×M×Q+N due to the superimposition of noise components N. For convenience's sake, the ideal total electromotive force V1=k×M×Q is hereinafter referred to as the true total electromotive force V1t.

### Signal Processing System 3

The signal processing system 3 is a system for the measuring system 1a and is configured to process a signal (in the present embodiment, the total electromotive force V1) outputted from the measuring system 1. The signal processing system 3 includes at least one (in the present embodiment, two, which is the same as the number of heat flow sensors 2) signal processing circuit 31 and a signal processing device 4. In the present embodiment, the signal processing circuits 31 are assigned to the multiple heat flow sensors 2 and are configured to process the total electromotive forces V1 outputted from the heat flow sensors 2.

Each signal processing circuit 31 includes a chopping circuit 311 as an electrical modulator, a switch controller 312, a filter circuit 313 as an extractor, and an amplifier 314.

The chopping circuit 311 is configured to receive the total electromotive force V1 as an electrical signal outputted from the thermoelectric conversion units 22. The chopping circuit 311 is configured to generate a modulated signal V2 by introducing a modulation including a predetermined modulation frequency fm to the received total electromotive force V1. The modulation frequency is a frequency outside the frequency band of the thermoelectric conversion units 22. The frequency outside the frequency band of the thermoelectric conversion units 22 refers to a frequency different from the frequencies of main frequency components of noise, such as electrical noise, magnetic noise, and electromagnetic noise, generated during the operation of the thermoelectric conversion units 22. The chopping circuit 311 may include a switch capable of interrupting the transmission of the electrical signal. In that case, the chopping circuit 311 is configured to perform a modulation by changing the switch between on and off on the basis of the predetermined modulation frequency fm. For example, the chopping circuit 311 outputs the total electromotive force V1 by changing the switch to ON and outputs not the total electromotive force V1 but, for example, zero voltage by changing the switch to OFF. In this way, the chopping circuit 311 modulates the total electromotive force V1. Thus, it outputs a square wave-shaped modulated signal V2 modulated such that the total electromotive force V1 and zero voltage are switched to each other over time. As seen above, the total electromotive force V1 is modulated using the relatively simple configuration that changes the switch between on and off.

The switch controller 312 is configured to output a signal for controlling the on and off of the switch of the chopping circuit 311 on the basis of a preset duty ratio, frequency, or the like. In the present embodiment, the switch controller 312 is configured to receive input of information required to control the state of the switch of the chopping circuit 311, such as the duty ratio, frequency, or the like and to output a signal for controlling the state of the switch of the chopping circuit 311 on the basis of the received information.

The filter circuit 313 is configured to extract a signal of a component of the modulation frequency fm from the modulated signal V2. For example, the filter circuit 313 is configured to transmit the component of the modulation frequency fm contained in the modulated signal V2 and to remove the main frequency components of noise. Preferably, the filter circuit 313 takes an appropriate form, such as a low-pass filter, high-pass filter, or band-pass filter, in accordance with the main frequency components of noise. Such a configuration selectively extracts the component of the modulation frequency fm from the total electromotive force V1, thereby reducing the effect of noise on the measuring system 1 and improving the accuracy of detection of the heat flow by the thermoelectric conversion unit 22.

The amplifier 314 is configured to amplify the modulated signal V2 whose noise components have been reduced through the filter circuit 313 and to output the resulting output signal V3. Note that each signal processing circuit 31 may include a filter circuit configured to transmit the component of the modulation frequency fm contained in the output signal V3 outputted from the amplifier 314 and to remove the main frequency components of noise. In this case, the filter circuit 313 is not essential.

The signal processing system 3 according to the present embodiment is configured to introduce a modulation into each of the total electromotive force V1 from a first heat flow sensor 2a and the total electromotive force V1 from a second heat flow sensor 2b. For example, the signal processing system 3 includes a signal processing circuit 31 for performing signal processing on the total electromotive force V1 from the first heat flow sensor 2a and a signal processing circuit 31 for performing signal processing on the total electromotive force V1 from the second heat flow sensor 2b.

### Signal Processing Device 4

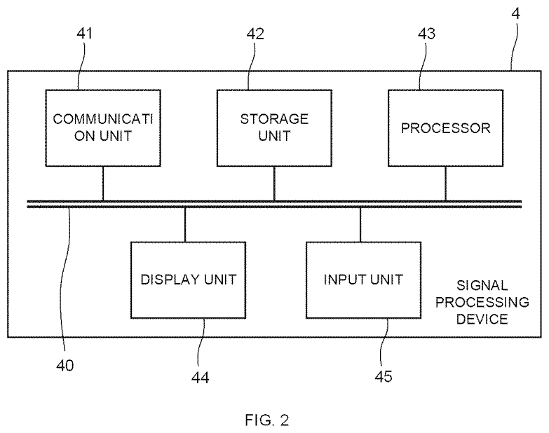

The signal processing device 4 is a device for processing the output signals V3 outputted from the signal processing circuits 31. FIG. 2 is a block diagram showing the hardware configuration of the signal processing device 4. The signal processing device 4 includes a communication unit 41, a storage unit 42, at least one processor 43 as an example of a control circuit, a display unit 44, and an input unit 45. These components are electrically connected through a communication bus 40 inside the signal processing device 4.

While the communication unit 41 preferably uses wired communication means such as USB, IEEE 1394, Thunderbolt®, or wired LAN network communication, it may use wireless LAN network communication, mobile communication such as 3G, LTE, or 5G, BLUETOOTH® communication, or the like as necessary. Preferably, the communication unit 41 is able to use a set of these multiple communication means.

That is, the signal processing device 4 may transmit and receive various types of information to and from the outside through the communication unit 41 and any network.

The storage unit 42 is storing various types of information defined by the above description. The storage unit 42 may be embodied, for example, as a storage device such as a solid-state drive (SSD) for storing various programs or the like related to the signal processing device 4 executed by the processor 43, or as memory such as random access memory (RAM) for storing temporarily required information (arguments, arrays, etc.) related to program calculations. The storage unit 42 is storing various programs, variables, and the like related to the signal processing device 4 executed by the processor 43.

The processor 43 processes and controls overall operation related to the signal processing device 4. The processor 43 is, for example, a central processing unit (CPU) (not shown). The processor 43 implements various functions related to the signal processing device 4 by reading a predetermined program stored in the storage unit 42. That is, when information processing by software stored in the storage unit 42 is specifically executed by the processor 43, which is an example of hardware, functional units included in the processor 43 are implemented. These will be described in more detail in the next section. Note that the processor 43 does not have to be a single processor but may include function-specific multiple processors 43. Or, the processor 43 may be a combination of these.

The display unit 44 may be contained in the housing of the signal processing device 4 or may be externally attached thereto. The display unit 44 displays a graphical user interface (GUI) screen operable by a user.

It is preferable to select a display device such as a CRT display, a liquid crystal display, an organic EL display, or a plasma display as the display unit 44 in accordance with the type of signal processing device 4.

The input unit 45 is configured to receive inputs from the user. The input unit 45 may be contained in the housing of the signal processing device 4 or may be externally attached thereto. For example, the input unit 45 may be embodied as a touchscreen integrated with the display unit 44. If the input unit 45 is a touchscreen, the user can make inputs by performing a tap operation, a swipe operation, and the like thereon. Of course, the input unit 45 may be a switch button, a mouse, a QWERTY keyboard, a voice recognition devices, a gesture measuring device, a gaze measuring device, a biosignal measuring device, an imaging device, or the like in place of a touchscreen. That is, the input unit 45 receives operation inputs made by the user. The input unit 45 transmits signals corresponding to the operation inputs to the processor 43 through the communication bus 40 as a response. The processor 43 may perform predetermined control or calculation as necessary.

The processor 43 is configured to acquire information from the signal processing device 4 or other devices. The processor 43 is also configured to acquire various types of information by reading various types of information stored in a storage area, which is at least a part of the storage unit 42, and writing the read information into a work area, which is at least a part of the storage unit 42.

The storage area is, for example, an area of the storage unit 42 embodied as a storage device such as a SSD.
The work area is, for example, an area embodied as memory such as RAM. Acquisition by the processor 43 includes acquiring the output results of the functional units included in the processor 43.

The processor 43 is configured to extract a specific frequency component from the acquired information as an extractor. For example, the processor 43 may transform a signal included in the acquired information into a frequency spectrum using Fourier transform or the like and selectively extract the signal intensity at a specific frequency from the frequency spectrum.

The processor 43 is configured to display various types of information. The processor 43 can display various types of information to the user through the display unit 44 of the signal processing device 4 or other devices. For example, the processor 43 controls the display unit 34 of the signal processing device 4 so that the display unit 34 displays visual information such as screens, images including still or moving images, icons, or messages. The processor 43 may generate only rendering information for displaying visual information on the display unit 44.

### 2.2 Flow of Signal Processing Related to Measuring System 1a

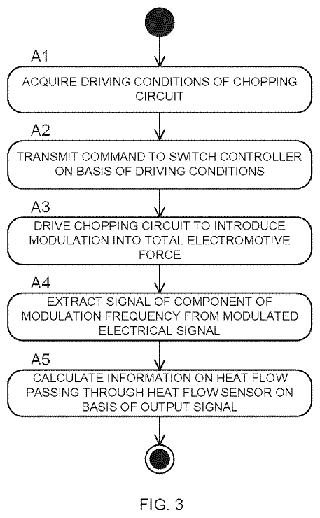

FIG. 3 is an activity diagram showing an example of signal processing performed by the measuring system 1a. The information processing may include any exception handling (not shown). The exception handling includes interruption of the information processing and omission of each process. Selection or input in the information processing may be performed on the basis of a user operation, or automatically without depending on a user operation.

### Activity A1

First, in activity A1, the processor 43 acquires the driving conditions of the chopping circuit 311. The driving conditions are conditions related to parameters for determining the driving mode of a switching element included in the chopping circuit 311 and may include, for example, the modulation frequency fm, the duty ratio, and the like that define the main frequency components of the modulation introduced into the total electromotive force V1 outputted from the heat flow sensor 2. The driving conditions may be conditions inputted by the user, or predetermined conditions, or conditions automatically determined on the basis of spectral analysis of the inputted total electromotive force V1. Preferably, the modulation frequency fm is a frequency different from the frequency band of the noise components superimposed on the total electromotive force V1.

The frequency band of the noise components is a frequency band consisting of main frequency components of noise that can be superimposed on the total electromotive forces V1 of the thermoelectric conversion units 22, such as the frequency band of noise caused by the intrinsic characteristics of the thermoelectric conversion units 22 or a main frequency band of noise unavoidably introduced to the thermoelectric conversion units 22. Examples of such noise include electromagnetic noise (e.g., electrical noise or electromagnetic wave noise) superimposed on the circuit through which the total electromotive force V1 is transmitted from the heat flow sensor 2 to the signal processing system 3, electromagnetic noise applied to elements such as the thermoelectric conversion units 22, and the like.

### Activity A2

Next, in activity A2, the processor 43 transmits a command to the switch controller 312 on the basis of the acquired driving conditions. In the present embodiment, the processor 43 transmits commands to the respective switch controllers 312 of the multiple signal processing circuits 31.

### Activity A3

Next, in activity A3, the switch controller 312 transmits a signal for controlling the switch of the chopping circuit 311 to the chopping circuit 311 so that the chopping circuit 311 is driven to introduce a modulation to the total electromotive force V1, in accordance with the driving conditions transmitted from the processor 43. Thus, the switch of the chopping circuit 311 is changed between on and off in a period including the modulation frequency fm as a main frequency component. In the present embodiment, when the switch of the chopping circuit 311 is changed to off, the modulated signal V2 outputted from the chopping circuit 311 becomes zero, and when the switch of the chopping circuit 311 is changed to on, the modulated signal V2 outputted from the chopping circuit 311 becomes a finite value (for example, the total electromotive force V1). That is, the chopping circuit 311 introduces a modulation to the total electromotive force V1 such that zero and the total electromotive force V1 are changed to each other at the predetermined modulation frequency fm. As a result, the chopping circuit 311 outputs the modulated signal V2 obtained by introducing the modulation to the total electromotive force V1.

In other words, the chopping circuit 311 is configured to introduce, as a modulator, the modulation including the predetermined modulation frequency fm into the total electromotive force V1, which is an electrical signal outputted from the thermoelectric conversion units 22. The processor 43 may introduce the modulation directly to the total electromotive force V1 not through the switch controller 312 and the chopping circuit 311. As described above, the chopping circuit 311 is configured to, as an electrical modulator, change the total electromotive force V1, which is an electrical signal outputted from the thermoelectric conversion units 22, such that electrical characteristics of the circuit through which the total electromotive force V1 is transmitted from the thermoelectric conversion units 22 to the filter circuit 313 as an extractor (in the present embodiment, resistance characteristics that define the transmission characteristics of the total electromotive force V1) are synchronized with the modulation frequency fm. Such a configuration extracts the signal less susceptible to intrinsic noise induced in the thermoelectric conversion units 22 while suppressing an increase in such noise. This circuit includes a switch capable of interrupting the transmission of the total electromotive force V1 as an electrical signal. The processor 43 modulates the total electromotive force V1 by changing the switch of the chopping circuit 311 between on and off on the basis of the modulation frequency fm. Such a configuration simplifies the mechanism for modulating the total electromotive force V1. The term “synchronize” means that two signals are synchronized with each other in the same period, regardless of whether there is a phase difference. The processor 43 may be configured to function as a modulator (specifically, an electrical modulator). In other words, the modulator may be implemented as a control circuit consisting of the processor 43.

### Activity A4

Next, in activity A4, the filter circuit 313 extracts a signal of a frequency component to be amplified associated with the modulation from the modulated signal V2 outputted by the chopping circuit 311. For example, the filter circuit 313 extracts a signal of a component of the modulation frequency fm. Thus, the filter circuit 313 outputs an output signal V3. This extraction may be performed by a digital circuit implemented by the processor 43. In other words, the processor 43 may function as an extractor in place of, or in addition to, the filter circuit 313. In the present embodiment, the output signal V3 extracted by the filter circuit 313 is amplified by the amplifier 314 as appropriate and transmitted to the signal processing device 4.

### Activity A5

Next, in activity A5, the processor 43 detects the heat flow passing through the heat flow sensor 2 in the z-axis direction (in other words, the temperature gradient in the z-axis direction that occurs in the heat flow sensor 2) on the basis of the output signal V3. The processor 43 calculates the heat flow from the output signal V3 on the basis of, for example, a predetermined relational expression (a proportional coefficient or offset) between the output signal V3 and the heat flow. The processor 43 outputs the calculated heat flow as the detected heat flow. Information on the heat flow detected by the processor 43 can be used for various purposes, such as presentation to the user or control of a device. The signal processing system 3 then ends this signal processing.

Such signal processing allows for selective extraction of the component of the modulation frequency fm from the total electromotive force V1. This allows for a reduction in the effect of noise that can be included in the total electromotive force V1 of the measuring system 1 and an improvement in the accuracy of detection of the heat flow by the thermoelectric conversion units 22.

### 2.3 State Transitions of Electrical Signal Subjected to Signal Processing

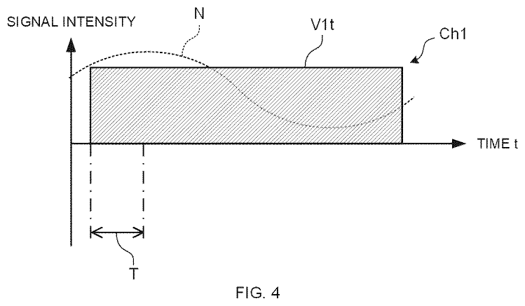

This section describes the state transitions of the electrical signal subjected to the signal processing described in the previous section, with reference to FIGS. 4 to 6.

FIG. 4 is a diagram showing changes over time in the total electromotive force V1 outputted from one heat flow sensor 2. As shown in FIG. 4, the total electromotive force V1 can include the true total electromotive force V1t and the noise components N, as described above. In the following description, for convenience's sake, it is assumed that the temperature gradient that occurs in the heat flow sensor 2 does not vary over time and the true total electromotive force V1t is constant. The noise components N are voltages generated by, for example, electromagnetic noise applied to the thermoelectric conversion units 22, electromagnetic noise that occurs in the circuit from the heat flow sensor 2 to the signal processing system 3, and the like. The total electromotive force V1 is transmitted to the signal processing system 3 with the noise components N superimposed on the true total electromotive force V1t. In the present embodiment, it is assumed that the frequency band of the noise components N is lower than the modulation frequency fm. In other words, it is assumed that main periods of the noise components N are longer than a period T defined by the modulation frequency fm.

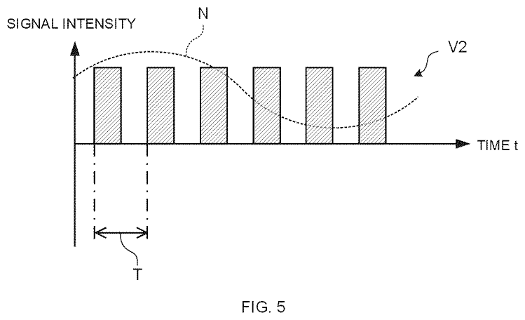

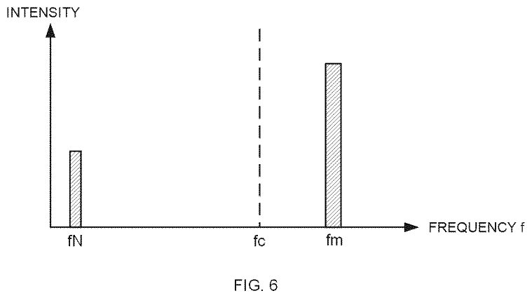

FIG. 5 is a diagram showing changes over time in the modulated signal V2. FIG. 6 is a diagram showing an example of the frequency spectrum of the modulated signal V2 shown in FIG. 5. As shown in FIG. 5, the modulated signal V2, which is obtained from chopping of the total electromotive force V1 by the chopping circuit 311, changes so as to oscillate between 0 and the total electromotive force V1 in the period T (=1/fm) defined by the modulation frequency fm. In this case, as shown in FIG. 6, the frequency spectrum of the total electromotive force V1 has a peak at noise frequencies fN, which are the frequencies of the noise components N and a peak at the modulation frequency fm introduced in the modulation. When the filter circuit 313 whose cutoff frequency fc is between the noise frequencies fn and the modulation frequency fm is used, the filter circuit 313 can cut the peak components of the noise frequencies fn included in the modulated signal V2 and selectively transmit the modulation frequency fm included in the modulated signal V2 fm. The signal processing system 3 then amplifies the resulting modulated signal V2, from which the noise components N have been reduced, to obtain the output signal V3 including less noise than when using conventional systems.

### 3. Measuring System According to Second Embodiment

This section describes a measuring system 1b according to a second embodiment (hereinafter simply referred to as the “measuring system 1b”). In the description of the measuring system 1b, the same components as those of the above measuring system 1a are given the same reference signs and therefore the description thereof may be omitted.

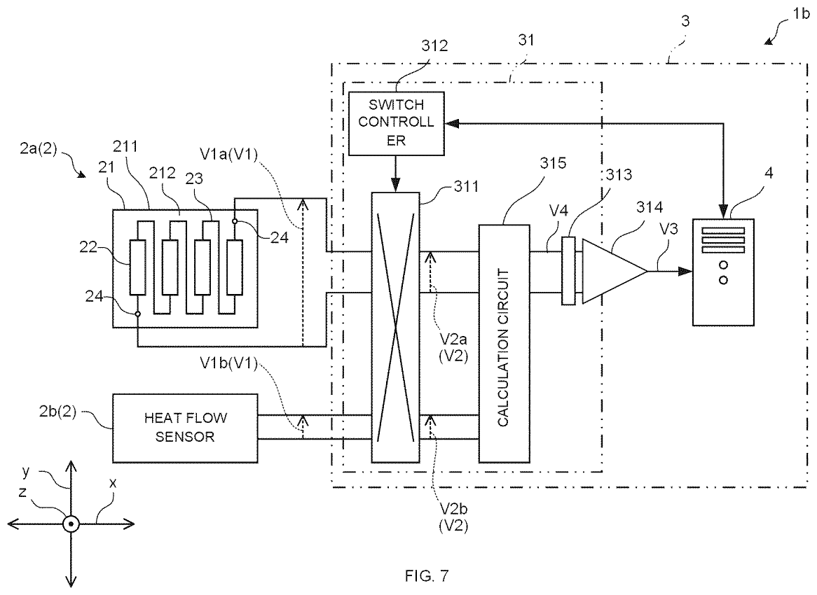

FIG. 7 is a diagram showing an example configuration of the measuring system 1b. As shown in FIG. 7, the measuring system 1b includes multiple heat flow sensors 2 and a signal processing system 3.

In the present embodiment, the heat flow sensors 2 includes a first heat flow sensor 2a and a second heat flow sensor 2b. The first heat flow sensor 2a and second heat flow sensor 2b are disposed such that approximately the same temperature gradient occurs in both the heat flow sensors. The first heat flow sensor 2a and second heat flow sensor 2b are configured to output total electromotive forces V1 having opposite signs on the basis of the same temperature gradient. Specifically, the thermoelectric conversion units 22 of the first heat flow sensor 2a and the thermoelectric conversion units 22 of the second heat flow sensor 2b are configured such that the polarities (e.g., the directions of magnetization M) thereof are opposite. For this reason, on the basis of a certain amount of heat transfer Q and the same noise components N, the first heat flow sensor 2a outputs the total electromotive force V1 that is k×M×Q+N as described above, while the second heat flow sensor 2b outputs −k×M×Q+N. The specific configuration of the first heat flow sensor 2a and second heat flow sensor 2b is similar to that of the heat flow sensor 2 of the measuring system la except that the first heat flow sensor 2a and second heat flow sensor 2b have different polarities. For convenience's sake, the total electromotive force V1 outputted from the first heat flow sensor 2a is referred to as the first total electromotive force V1a, and the total electromotive force V1 outputted from the second heat flow sensor 2b is referred to as the second total electromotive force V1b.

As with the signal processing system 3 of the measuring system 1a, the signal processing system 3 of the measuring system 1b includes a signal processing circuit 31 and a signal processing device 4. The specific hardware configuration of the signal processing device 4 of the measuring system 1b is similar to that of the signal processing device 4 of the measuring system 1a and therefore will not be described.

The signal processing circuit 31 of the measuring system 1b differs from the signal processing circuit 31 of measuring system 1a in that it includes the chopping circuit 311, the switch controller 312, the filter circuit 313, and the amplifier 314, as well as a calculation circuit 315.

The filter circuit 313 of the measuring system 1b is configured to introduce a modulation based on the modulation frequency fm into each of the first total electromotive force V1a and second total electromotive force V1b. Thus, the filter circuit 313 generates a first modulated signal V2a, which is a modulated signal V2 obtained by introducing the modulation to the first total electromotive force V1a, and a second modulated signal V2b, which is a modulated signal V2 obtained by introducing the modulation to the second modulated signal V2b.

The calculation circuit 315 of the measuring system 1b is configured to perform a calculation on the first total electromotive force V1a and second total electromotive force V1b such that the common noise components N contained in the first total electromotive force V1a and second total electromotive force V1b are reduced, to generate a calculated electrical signal V4. For example, the calculation circuit 315 may be a subtraction circuit that outputs an electrical signal corresponding to the difference between the first modulated signal V2a and the second modulated signal V2b as the calculated electrical signal V4. The calculation circuit 315 may also be an addition circuit that outputs an electrical signal corresponding to the sum of the first modulated signal V2a and the second modulated signal V2b as the calculated electrical signal V4. The calculated electrical signal V4 is an electrical signal into which the modulation has been introduced and is an example of the modulated signal V2.

The filter circuit 313 extracts a signal of a frequency component to be amplified due to the modulation from the calculated electrical signal V4 outputted by the calculation circuit. Thus, the filter circuit 313 outputs an output signal V3. The filter circuit 313 of the measuring system 1b may extract a signal of a component of the modulation frequency fm as is done by the filter circuit 313 of the measuring system 1a, or may extract a signal to be amplified in a calculation by the calculation circuit 315 from the modulated signal V2. The signal to be amplified in a modulation does not include signals that can be amplified (added) in a calculation regardless of whether the signals have been modulated, such as the noise components N.

The processor 43 of the signal processing device 4 may perform the above signal processing of the measuring system 1a on the output signal V3 to obtain information on the heat flow.

In this case, for example, in activity A1, the processor 43 may set driving conditions on each of the chopping circuits 311 of the multiple signal processing circuits 31. Preferably, the processor 43 sets driving conditions such that the chopping circuit 311 of the signal processing circuit 31 for processing the total electromotive force V1 from the first heat flow sensor 2a and the chopping circuit 311 of the signal processing circuit 31 for processing the total electromotive force V1 from the second heat flow sensor 2b modulate the respective total the electromotive forces V1 on the basis of the same modulation frequency fm. By performing a calculation on the multiple total electromotive forces V1 thus modulated, for example, by subtracting the respective components of the modulation frequency fm from each other, the noise components can be more suitably removed.

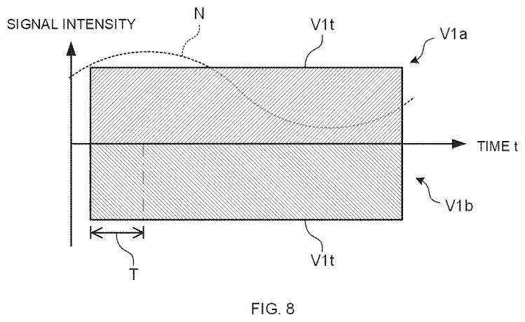

Next, an example of changes in the state of the electrical signal due to the signal processing performed by the measuring system 1b will be described with reference to FIGS. 8 to 10. In the following description, for convenience's sake, it is assumed that the calculation circuit 315 is a subtraction circuit and that a modulation is introduced into the first total electromotive force V1a and second total electromotive force V1b so that a phase difference of 180 degrees appears between the first modulated signal V2a and the second modulated signal V2b.

FIG. 8 is a diagram showing changes over time in the first total electromotive force V1a and second total electromotive force V1b. For convenience's sake, it is assumed that the true total electromotive forces V1t contained in the first total electromotive force V1a and second total electromotive force V1b are constant. As shown in FIG. 8, the true total electromotive force V1t outputted from the first heat flow sensor 2a and the true total electromotive force V1t outputted from the second heat flow sensor 2b have opposite signs. In the first total electromotive force V1a and second total electromotive force V1b, the common noise components N are superimposed on the respective true total electromotive forces V1t.

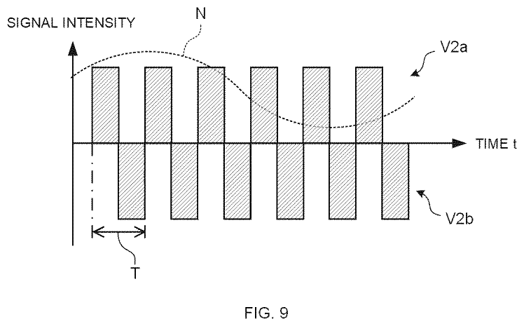

FIG. 9 is a diagram showing changes over time in the first modulated signal V2a and second modulated signal V2b. The first modulated signal V2a is similar to that described with reference to FIG. 5 and therefore will not be described. In the present embodiment, the chopping circuits 311 receive the total electromotive forces V1a and V1b from the two heat flow sensors 2a and 2b, respectively, and chop them in different phases (specifically, opposite phases). As a result, as with the first modulated signal V2a, the second modulated signal V2b is modulated to have the periodicity of the same modulation frequency fm. The sign of the signal intensity (i.e., voltage) of the second modulated signal V2b is opposite to that of the first modulated signal V2a. The phase of the second modulated signal V2b is also opposite to that of the first modulated signal V2a. A calculated electrical signal obtained by taking the difference between the first modulated signal V2a and the second modulated signal V2b is almost constant and has a frequency component of a frequency of almost zero as a peak or a frequency component corresponding to the modulation frequency fm as a peak.

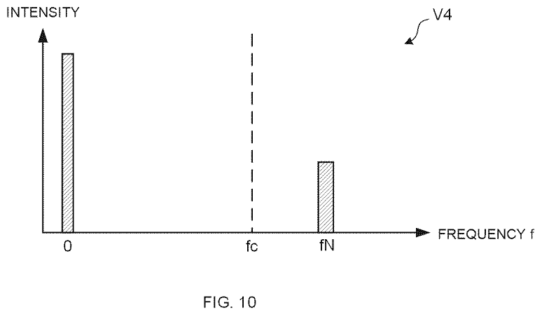

FIG. 10 is a diagram showing an example of the frequency spectrum of the calculated electrical signal V4 obtained by subtracting the first modulated signal V2a and second modulated signal V2b shown in FIG. 9 from each other using the calculation circuit 315. As shown in FIG. 10, the calculated electrical signal V4 has a peak in a frequency band of almost zero. For this reason, by using a low-pass filter or the like as the filter circuit 313, the signal processing circuit 31 reduces frequency components equal to or higher than the cutoff frequency fc and transmits frequency components lower than the cutoff frequency fc. Thus, the noise components N of the noise frequencies fN are reduced.

When an addition circuit is used as the calculation circuit 315, the calculated electrical signal V4 has a frequency spectrum similar to that shown in FIG. 6. In this case, the component of the modulation frequency fm of the calculated electrical signal is amplified to twice that of the modulated signal V2 and amplified to a greater extent than the noise components N.

The signal processing circuits 31 may be implemented as digital circuits by the signal processing device 4. For example, the signal processing device 4 may directly acquire the modulated signals V2 modulated by the chopping circuit 311 and Fourier transform them to extract the frequency components related to the modulation frequency fm. The signal processing device 4 may also perform the above signal processing on each of the modulated signals V2 based on the total electromotive forces V1 outputted from the multiple heat flow sensors 2 and sample the resulting information on the heat flows as appropriate to output more reliable information on the heat flows.

### 4. Measuring System According to Third Embodiment

This section describes a measuring system 1c according to a third embodiment (hereinafter simply referred to as the measuring system 1c). In the description of measuring system 1c, the same components as those of the measuring system 1a or measuring system 1b are given the same reference signs and therefore the description thereof may be omitted.

### 4.1.1 Example Configuration of Measuring System 1c

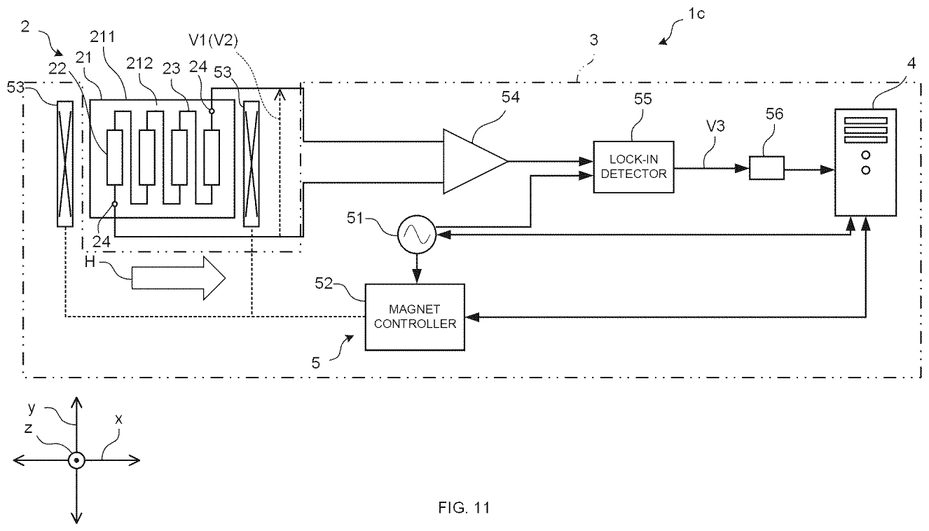

FIG. 11 is a diagram showing an example configuration of the measuring system 1c. As shown in FIG. 11, the measuring system 1c includes a heat flow sensor 2 and a signal processing system 3. The heat flow sensor 2 is similar to that of the measuring system 1a.

The signal processing system 3 of the measuring system 1c includes a signal processing circuit 5 in place of (or in addition to) the signal processing circuit 31. The signal processing circuit 5 includes an oscillator 51, a magnet controller 52, a magnetic field application unit 53, an amplifier 54, and a lock-in detector 55 as an extractor. As with those of the measuring system 1a and measuring system 1b, the signal processing system 3 of the measuring system 1c includes a signal processing device 4. The hardware configuration of the signal processing device 4 is similar to that described above.

The oscillator 51 is configured to output signals of the modulation frequency fm. For example, the oscillator 51 generates continuous periodic signals (e.g., sinusoidal signals) that oscillate at the modulation frequency fm. The oscillator 51 may be disposed outside the signal processing circuit 5 or outside the signal processing system 3. The oscillation frequency of the oscillator 51 can be controlled by the signal processing device 4. According to such a configuration, more diverse noise can be reduced by setting an appropriate modulation frequency fm in accordance with the frequency band of noise.

The magnet controller 52 is configured to generate an input signal for driving the magnetic field application unit 53 (to be discussed later), on the basis of a signal from the oscillator 51. The driving mode of the magnet controller 52 can be controlled by the signal processing device 4. For example, the magnet controller 52 can be controlled by the signal processing device 4 as to whether the magnet controller 52 outputs an input signal.

The magnetic field application unit 53 is configured to apply an external magnetic field H to the heat flow sensor 2 (specifically, thermoelectric conversion units 22). For example, the magnetic field application unit 53 applies the external magnetic field H such that the magnetization direction of the magnetic domains of the thermoelectric conversion units 22 can be reversed. In other words, the magnetic field application unit 53 may be configured to apply the external magnetic field to the thermoelectric conversion units 22 such that the sign of an element based on the anomalous Nernst effect of the thermoelectric tensor of each thermoelectric conversion unit 22 is reversed by the external magnetic field H. Such a configuration reverses the sign of the element of the thermoelectric tensor using the external magnetic field H, thereby amplifying the signal intensity in a band of the modulation frequency fm of the electrical signal (the total electromotive force V1) outputted from heat flow sensor 2. For example, the magnetic field application unit 53 may be disposed with respect to the thermoelectric conversion units 22 such that the external magnetic field H applied to the thermoelectric conversion units is induced along an x-axis direction, which is an in-plane direction. Such a configuration easily applies a modulation to the magnetic domains by inducing a small in-plane magnetic field to the thin films, thereby further amplifying the signal intensity in the band of the modulation frequency. In the present embodiment, the magnetic field application unit 53 is configured to apply the external magnetic field H along the x-axis direction, which is the magnetization direction of the magnetic domains of the thermoelectric conversion units 22.

The magnetic field application unit 53 is also configured to indirectly acquire a signal from the oscillator 51 through the magnet controller 52 and to apply the external magnetic field H on the basis of an input signal outputted from the magnet controller 52. Thus, the magnetic field application unit 53 is configured to apply the external magnetic field H including the modulation frequency fm to the thermoelectric conversion units. Such a configuration introduces a disturbance to the thermoelectric conversion units 22 in a non-contact manner, thereby reducing the possibility that contact noise, such as contact resistance, can be superimposed on the electrical signal. More specifically, any configuration capable of electrically or mechanically controlling the polarity of the external magnetic field H, such as a permanent magnet, an electromagnet, or a coil, may be used as the magnetic field application unit 53.

The amplifier 54 is configured to amplify a signal outputted from the output unit 24. The specific configuration of the amplifier 54 is similar to that of the amplifier 314.

The lock-in detector 55 is configured to acquire the electrical signal outputted from the heat flow sensor 2 and amplified by the amplifier 54 and to extract a signal component of the modulation frequency fm from the electrical signal using a lock-in method based on a signal from the oscillator 51. The extracted signal is transmitted to the signal processing device 4, which then outputs information on the heat flow on the basis of the signal.

When the magnetic field application unit 53 applies the external magnetic field H that oscillates periodically in accordance with the modulation frequency fm, to the heat flow sensor 2, the thermoelectric tensor of each thermoelectric conversion unit 22 is modulated in a period corresponding to the modulation frequency fm. Thus, the electromotive force itself generated by each thermoelectric conversion unit 22 on the basis of the heat flow is modulated in the period corresponding to the modulation frequency fm, and the total electromotive force V1 itself is outputted as the modulated signal V2 into which the modulation by the external magnetic field H has been introduced. The outputted modulated signal V2 is amplified by the amplifier 314. As a result, the lock-in detector 55 is configured to extract a signal of the modulation frequency fm from the modulated signal V2 using the lock-in method based on the signal from the oscillator 51. Such a configuration improves the accuracy of synchronization of the signal and further reduces the noise components.

The signal processing circuit 5 may further include a filter circuit 56. The filter circuit 56 is configured to selectively transmit components in the frequency band of the modulation frequency fm from the output signal V3 extracted by the lock-in detector 55. Preferably, the filter circuit 56 is designed appropriately as a low-pass filter, a high-pass filter, a band-pass filter, or the like in accordance with the relationship between the modulation frequency fm and the frequencies of the noise components N.

### 4.2.1. Example of Magnetic Field Application Unit

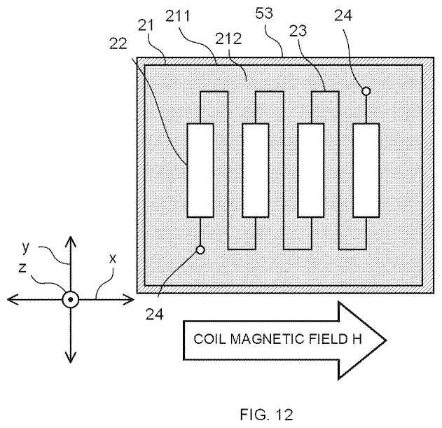

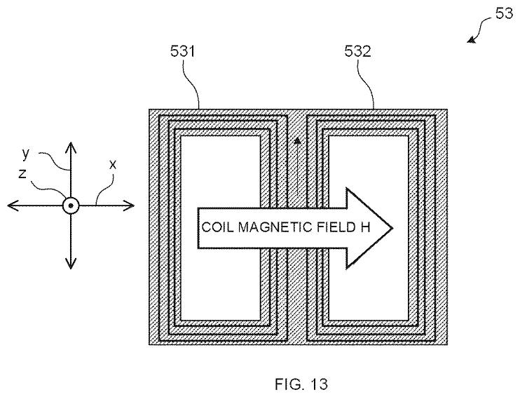

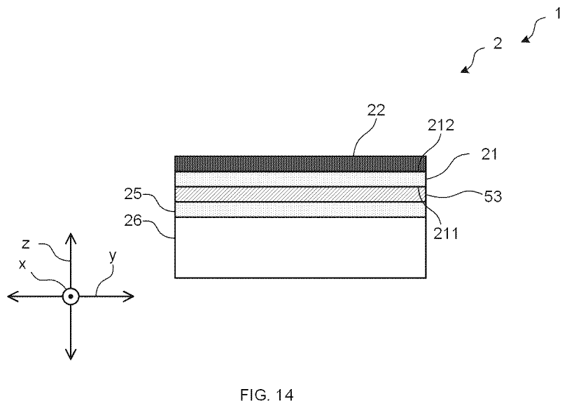

This section describes an example of the magnetic field application unit 53 included in the measuring system 1c described in the previous section. The magnetic field application unit 53 according to the present embodiment is incorporated in the heat flow sensor 2. FIG. 12 is a plan view from the z-axis of the heat flow sensor 2 in which the magnetic field application unit 53 is incorporated. FIG. 13 is a plan view from the z-axis of the magnetic field application unit 53 incorporated in the heat flow sensor 2. FIG. 14 is a cross-sectional view of a surface including the z-axis direction of the heat flow sensor 2 shown in FIG. 12.

As shown in FIGS. 12 to 14, the magnetic field application unit 53 is disposed on the connecting surface 211 of a substrate 21. The substrate 21 consists of an insulator. For this reason, the magnetic field application unit 53 is electrically insulated from the thermoelectric conversion units 22 disposed on the measuring surface 212 of the substrate 21. The magnetic field application unit 53 according to the present embodiment is formed as a multilayer body layered on the connecting surface 211. As shown in FIG. 13, the magnetic field application unit 53 includes a first coil 531 as a first magnetic field generation element and a second coil 532 as a second magnetic field generation element. The first coil 531 and the second coil 532 are mounted on the connecting surface 211 as coil patterns layered in a square spiral shape along the z-axis direction. The first coil 531 and second coil 532 are configured to apply a magnetic field in the z-axis direction when a current is passed therethrough. The first coil 531 and second coil 532 are aligned along the x-axis direction, which is the magnetization direction of the thermoelectric conversion unit 22.

When the polarity of the first coil 531 and the polarity of the second coil 532 are opposite, magnetic field lines generated from the N pole of the first coil 531 extend toward the S pole of the second coil 532 and magnetic field lines generated from the N pole of the second coil 532 extend toward the N pole of the first coil 531. As a result, a circular external magnetic field H around the y-axis direction is formed. Thus, at least a portion of the external magnetic field H is induced to the thermoelectric conversion units 22 along the x-axis direction, which is an in-plane direction of the thin films that are the thermoelectric conversion units 22. Defining the positional relationship between the first coil 531 and the second coil 532 and setting the polarities in accordance with the positional relationship as described above is an example of generating a magnetic field on the basis of an input signal having a phase difference corresponding to the positional relationship between the first coil 531 and the second coil 532. Such a configuration realizes a signal processing system that is integral with the thermoelectric conversion units 22 and is more compact. The first coil 531 and second coil 532 may have opposite chiralities. In this case, the first coil 531 and second coil 532 may be connected in series. According to such a configuration, when a current passed through the first coil 531 is transferred to the second coil 532, the polarities of the first coil 531 and second coil 532 are reversed. Thus, the control of the first coil 531 and second coil 532 is simplified.

The magnetic field application unit 53 may be formed such that its outer edge surrounds the connecting surface 211 when the substrate 21 is seen in a plan view from the z-axis direction. Such a configuration facilitates application of the external magnetic field H to the entire thermoelectric conversion units 22 disposed on the measurement surface 212. The first coil 531 and second coil 532 may be disposed to be away from each other in the x-axis direction. Such a configuration facilitates application of the external magnetic field H along the y-axis direction to the thermoelectric conversion units 22.

As shown in FIG. 14, the heat flow sensor 2 may include the substrate 21, the thermoelectric conversion units 22, wiring 23, and the output unit 24, as well as an insulating layer 25 and a heat sink 26. The insulating layer 25 is an electrical insulator stacked on the connecting surface 211 of the substrate 21 through the magnetic field application unit 53. Preferably, the insulating layer 25 has thermal conductivity. The heat sink 26 is stacked on the connecting surface 211 through the insulating layer 25. The heat sink 26 is connected to a heat bath (not shown) and has a temperature within a predetermined range. The temperature of the heat sink 26 is transferred to the measuring surface 212 through the insulating layer 25, the magnetic field application unit 53, and the substrate 21. As a result, in a steady state, the temperature of areas in contact with the measuring surface 212 of the thermoelectric conversion units 22 is approximately equal to the temperature of the heat sink 26. Thus, the temperature defining the temperature gradient in the z-axis direction in each thermoelectric conversion unit 22 is stabilized. This facilitates evaluation of the temperature near each thermoelectric conversion units 22 from the temperature gradient in the thermoelectric conversion unit 22, that is, from the heat flow passing through the thermoelectric conversion unit 22. The heat sink 26 is applicable not only to the measuring system 1c, but also to the above measuring systems 1a and 1b.

### 4.3.3. Example of Signal Processing Performed by Measuring System 1c

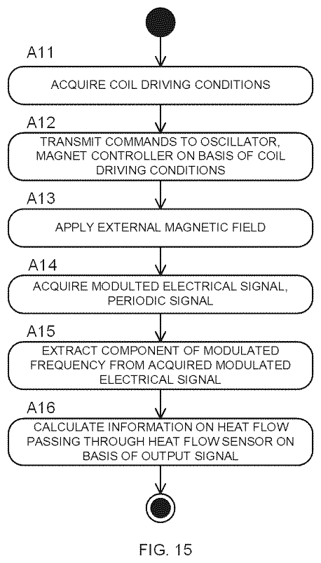

This section describes an example of signal processing performed by the measuring system 1c described in sections 4.1 and 4.2. FIG. 15 is an activity diagram showing an example of signal processing performed by the measuring system 1c.

### Activity A11

First, in activity A11, the processor 43 acquires the driving conditions of the coils 531 and 532 included in the magnetic field application unit 53 (hereinafter referred to as the coil driving conditions for convenience's sake). The coil driving conditions may include any information on parameters that define the external magnetic field H, such as the amplitude, direction, and modulation frequency fm of the external magnetic field H. The coil driving conditions may be conditions inputted by a user through the input unit 45 or may be conditions set automatically by the processor 43 or the like.

### Activity A12

Next, in activity A12, the processor 43 transmits commands to the oscillator 51 and magnet controller 52 on the basis of the acquired coil driving conditions. Thus, the oscillator 51 generates a periodic signal that oscillates at the modulation frequency fm included in the coil driving conditions. The magnet controller 52 determines the parameters of input signals to be passed through the first coil 531 and the second coil 532 on the basis of the periodic signal generated by the oscillator 51 and the command transmitted from the processor 43 and outputs alternating currents as the input signals to the first coil 531 and the second coil 532 on the basis of the determined parameters. Examples of the parameters include the amplitude (in other words, the amplitude of the external magnetic field H), waveform, and frequency (the modulation frequency fm) of the alternating currents to be outputted to the first coil 531 and the second coil 532, the phase difference between the current to be passed through the first coil 531 and the current to be passed through the second coil 532, and the like. In the present embodiment, the magnet controller 52 outputs, as the input signals, sinusoidal alternating currents of the modulation frequency fm, synchronized with the periodic signal of the oscillator 51.

### Activity A13

Next, in activity A13, the magnetic field application unit 53 applies the external magnetic field H to the heat flow sensor 2 on the basis of the input signals outputted from the magnet controller 52. Thus, a magnetic modulation of the modulation frequency fm is introduced into each of the thermoelectric conversion units 22 of the heat flow sensor 2. In other words, the processor 43 performs a magnetic field modulation step of introducing, by the magnetic field application unit 53, a modulation to the thermoelectric conversion units 22 by applying the external magnetic field including the modulation frequency thereto. Such a configuration introduces a disturbance to the thermoelectric conversion units 22 in a non-contact manner, thereby reducing the possibility that contact noise such as contact resistance can be superimposed on the electrical signal. The processor 43 may use the magnetic field application unit 53 to apply the external magnetic field H with an amplitude that reverses the magnetization direction of the magnetic domains of the thermoelectric conversion units 22. In other words, the processor 43 may use the magnetic field application unit 53 to apply the external magnetic field H with an amplitude higher than the coercivity of the thermoelectric conversion units 22. Thus, the sign of the element based on the anomalous Nernst effect of the thermoelectric tensor of each thermoelectric conversion unit 22 is reversed. In other words, the processor 43 may introduce a modulation by controlling the magnetic field application unit 53 to reverse the sign of the element based on the anomalous Nernst effect of the thermoelectric tensor of each thermoelectric conversion unit 22 using the external magnetic field H. Such a configuration reverses the sign of the element of the thermoelectric tensor using the external magnetic field H, thereby amplifying the signal intensity in the band of the modulation frequency fm of the electrical signal. The processor 43 may also introduce a modulation by inducing the external magnetic field H to the thermoelectric conversion units 22 along an in-plane direction (e.g., the x-axis direction) using the magnetic field application unit 53. Such a configuration easily applies a modulation to the magnetic domains by inducing a small in-plane magnetic field to the thin films, thereby further amplifying the signal intensity in the band of the modulation frequency fm.

The heat flow sensor 2 generates the total electromotive force V1 on the basis of the heat flow in the z-axis direction. The thermoelectric conversion units 22 each generate an electromotive force on the basis of the heat flow in the z-axis direction while being subjected to a modulation including the modulation frequency fm by the external magnetic field H. This means that the modulation is directly introduced to the electromotive force itself outputted from each thermoelectric conversion unit 22. Thus, the heat flow sensor 2 outputs the modulated signal V2, which is the modulated total electromotive force V1, from the output unit 24. The outputted output unit 24 is amplified by the amplifier 54 and transferred to the lock-in detector 55.

### Activity A14

Next, in activity A14, the lock-in detector 55 acquires the modulated signal V2 outputted from the heat flow sensor 2 (specifically, the modulated signal V2 amplified by the amplifier 54) and the periodic signal outputted from the oscillator 51.

### Activity A15

Next, in activity A15, the lock-in detector 55 extracts a signal of the modulation frequency fm from the acquired modulated signal V2 using the lock-in method based on the signal from the oscillator. Such a configuration improves the accuracy of synchronization of the signal and further reduces the noise components. The lock-in detector 55 outputs the extracted signal to the signal processing device 4 as the output signal V3 through the filter circuit 56. The extraction of the signal using the lock-in method may be performed by the processor 43. In other words, the processor 43 may function as an extractor.

### Activity A16

The processor 43 acquires the output signal V3 outputted from the lock-in detector 55 and calculates information on the heat flow passing through the heat flow sensor 2 on the basis of the output signal V3. The details of this activity are similar to those of activity A5. The signal processing system 3 then repeats this signal processing and ends this signal processing in accordance with a user operation.

### Others

The above aspects of the measuring systems 1a, 1b, and 1c and signal processing system 3 are only illustrative and are not limiting. The above measuring systems 1a, 1b, and 1c can be combined as appropriate to the extent that they do not technically contradict each other. The above measuring systems 1a, 1b, and 1c can be modified as follows.

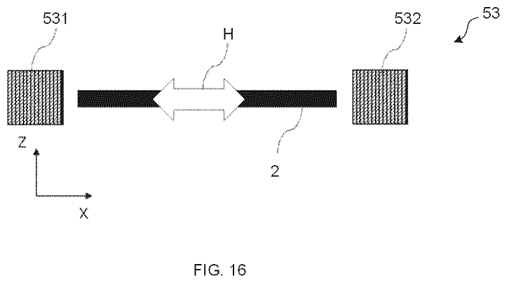

In the measuring system 1c, the magnetic field application unit 53 may be mounted separately from the heat flow sensor 2. FIG. 16 is a diagram showing another example of the magnetic field application unit 53. As shown in FIG. 16, the first coil 531 and second coil 532 may be disposed in positions away from the heat flow sensor 2 in the x-axis direction and may have a polarity in the x-axis direction. The number of coils as magnetic field application elements included in the magnetic field application unit 53 is any number and may be multiple or one.

In the measuring system 1c, the first coil 531 and second coil 532 do not have to be aligned in the x-axis direction but may have any positional relationship. For example, the first coil 531 may be disposed in a position away in the x-axis direction from one of the thermoelectric conversion units 22, and the second coil 532 may be disposed in a position away in the y-axis direction from one of the thermoelectric conversion units 22. In this case, the first coil 531 and second coil 532 may be configured such that the polarities thereof are opposite with a phase difference of 90 degrees. Thus, the external magnetic field H in the x-axis direction is applied to at least a portion of each thermoelectric conversion unit 22. The number of magnetic field application elements included in the magnetic field application unit 53 does not have to be two but may be any number. In other words, when a magnetic field is generated on the basis of an input signal having a phase difference corresponding to the positional relationship between the first coil 531 and the second coil 532, at least a portion of the external magnetic field H is induced to the thermoelectric conversion units 22 along the x-axis direction, which is an in-plane direction of the thin-film thermoelectric conversion units 22.

While, in the above embodiment, the signal processing system 3 has been described as being included in each of the measuring systems 1a, 1b, and 1c, such a distinction is hypothetical. In other words, the measuring system 1a, 1b, and 1c themselves may each constitute the signal processing system 3. In other words, the signal processing system 3 may include the heat flow sensor 2.

While, in the above embodiment, the signal processing device 4 performs various types of storage and control, multiple external devices may be used in place of the signal processing device 4. In other words, the various types of information and programs may be distributed and stored in other multiple external devices using a blockchain technology or the like.

The signal processing system 3 includes at least one processor 43 capable of executing a program so that the steps of a signal processing method are performed. An aspect of the above embodiment may be a signal processing method. The signal processing method includes the components of a similar signal processing system. An aspect of the above embodiment may be a program. The program causes at least one computer to perform the steps of the signal processing method.

The signal processing system 3 does not have to include the amplifier 314. Similarly, the signal processing circuit 5 does not have to include the amplifier 54. The signal processing system 3 may include both the signal processing circuit 31 and signal processing circuit 5.

The signal processing system 1 or the like may be provided in aspects below.

(1) A signal processing method in a measuring system, the measuring system including a thermoelectric conversion unit configured to convert a temperature gradient generated by heat exchange with an object to be measured into an electrical signal on the basis of the anomalous Nernst effect, the signal processing method comprising: a modulation step of generating a modulated signal by introducing a modulation including a predetermined modulation frequency into the electrical signal outputted from the thermoelectric conversion unit, the modulation frequency being a frequency different from a frequency band of the thermoelectric conversion unit; and an extraction step of extracting a signal of a component of the modulation frequency from the modulated signal.

Such a configuration selectively extracts the modulation frequency component from the electrical signal, thereby reducing the effect of noise on the measuring system and improving the accuracy of detection of the heat flow by the thermoelectric conversion unit.

(2) The signal processing method according to (1), wherein the modulation step includes a magnetic field modulation step of introducing the modulation by applying an external magnetic field including the modulation frequency to the thermoelectric conversion unit.

Such a configuration introduces a disturbance to the thermoelectric conversion unit in a non-contact manner, thereby reducing the possibility that contact noise such as contact resistance can be superimposed on the electrical signal.

(3) The signal processing method according to (2), wherein the magnetic field modulation step includes introducing the modulation by reversing a sign of an element based on the anomalous Nernst effect of a thermoelectric tensor of the thermoelectric conversion unit using the external magnetic field.

Such a configuration reverses the element of the thermoelectric tensor using the external magnetic field, thereby amplifying the signal intensity in the band of the modulation frequency of the electrical signal.

(4) The signal processing method according to (2) or (3), wherein: the thermoelectric conversion unit is formed as a thin film and is configured to be magnetized along an in-plane direction of the thin film, and the magnetic field modulation step includes introducing the modulation by inducing the external magnetic field to the thermoelectric conversion unit along the in-plane direction.

Such a configuration easily applies the modulation to the magnetic domains by inducing a small in-plane magnetic field to the thin films, thereby further amplifying the signal intensity in the band of the modulation frequency.

(5) The signal processing method according to any one of (1) to (4), wherein the modulation step further includes an electrical modulation step of performing the modulation by changing electrical characteristics of a circuit through which the electrical signal outputted from the thermoelectric conversion unit is transmitted such that the electrical characteristics are synchronized with the modulation frequency.

Such a configuration extracts the signal less susceptible to intrinsic noise induced in the thermoelectric conversion unit while suppressing an increase in such noise.

(6) The signal processing method according to (5), wherein: the circuit includes a switch capable of interrupting transmission of the electrical signal, and the electrical modulation step includes performing the modulation by changing the switch between on and off on the basis of the modulation frequency.

Such a configuration simplifies the mechanism for modulating the electrical signal.

(7) A signal processing system in a measuring system, the measuring system including a thermoelectric conversion unit configured to convert a temperature gradient generated by heat exchange with an object to be measured into an electrical signal on the basis of the anomalous Nernst effect, the signal processing system comprising: a modulator configured to generate a modulated signal by introducing a modulation including a predetermined modulation frequency into the electrical signal outputted from the thermoelectric conversion unit, wherein the modulation frequency is a frequency outside a frequency band of the thermoelectric conversion unit; and an extractor configured to extract a signal of a component of the modulation frequency from the modulated signal.

Such a configuration selectively extracts the modulation frequency component from the electrical signal, thereby reducing the effect of noise on the measuring system and improving the accuracy of detection of the heat flow by the thermoelectric conversion unit.

(8) The signal processing system according to (7), further comprising a magnetic field application unit configured to apply an external magnetic field including the modulation frequency to the thermoelectric conversion unit.

Such a configuration introduces a disturbance to the thermoelectric conversion unit in a non-contact manner, thereby reducing the possibility that contact noise such as contact resistance can be superimposed on the electrical signal.

(9) The signal processing system according to (8), wherein the magnetic field application unit applies the external magnetic field to the thermoelectric conversion unit such that a sign of an element based on the anomalous Nernst effect of a thermoelectric tensor of the thermoelectric conversion unit is reversed by the external magnetic field.

Such a configuration reverses the element of the thermoelectric tensor using the external magnetic field, thereby amplifying the signal intensity in the band of the modulation frequency of the electrical signal.

(10) The signal processing system according to (8) or (9), wherein: the thermoelectric conversion unit is formed as a thin film and includes a magnetic domain configured to be magnetized along an in-plane direction of the thin film, and the magnetic field application unit is disposed with respect to the thermoelectric conversion unit such that the external magnetic field applied to the thermoelectric conversion unit is induced along the in-plane direction.

Such a configuration easily applies the modulation to the magnetic domains by inducing a small in-plane magnetic field to the thin films, thereby further amplifying the signal intensity in the band of the modulation frequency.

(11) The signal processing system according to (10), further comprising: the thermoelectric conversion unit; and an insulator having a first surface and a second surface opposite to the first surface in a thickness direction, wherein: the thermoelectric conversion unit is stacked on the first surface, the magnetic field application unit is disposed on the second surface so as to be electrically insulated from the thermoelectric conversion unit and comprises a first magnetic field generation element and a second magnetic field generation element, and when the first magnetic field generation element and the second magnetic field generation element generate a magnetic field on the basis of an input signal having a phase difference corresponding to a positional relationship between the first magnetic field generation element and the second magnetic field generation element such that at least a portion of the external magnetic field is induced to the thermoelectric conversion unit along the in-plane direction of the thin film that is the thermoelectric conversion unit.

Such a configuration realizes a signal processing system that is integral with the thermoelectric conversion units 22 and is more compact.

(12) The signal processing system according to any one of (7) to (11), wherein the modulator further includes an electrical modulator configured to change the electrical signal outputted from the thermoelectric conversion unit such that electrical characteristics of a transmission circuit through which the electrical signal is transmitted from the thermoelectric conversion unit to the extractor are synchronized with the modulation frequency.

Such a configuration extracts the signal less susceptible to intrinsic noise induced in the thermoelectric conversion unit while suppressing an increase in such noise.

(13) The signal processing system according to (12), wherein: the transmission circuit includes a switch capable of interrupting transmission of the electrical signal, and the electrical modulator is configured to perform the modulation by changing the switch between on and off on the basis of the modulation frequency.

Such a configuration simplifies the mechanism for modulating the electrical signal.

(14) The signal processing system according to any one of (7) to (13), wherein the extractor is configured to extract a signal of the modulation frequency from the modulated signal using a lock-in method based on a signal from an oscillator configured to output a signal of the modulation frequency.

Such a configuration improves the accuracy of synchronization of the signal and further reduces the noise components.

(15) A signal processing program in a measuring system, the measuring system including a thermoelectric conversion unit configured to convert a temperature gradient generated by heat exchange with an object to be measured into an electrical signal on the basis of the anomalous Nernst effect, the signal processing program being configured to cause at least one computer to perform: a modulation step of generating a modulated signal by introducing a modulation including a predetermined modulation frequency into the electrical signal outputted from the thermoelectric conversion unit, the modulation frequency being a frequency different from a frequency band of the thermoelectric conversion unit; and an extraction step of extracting a signal of a component of the modulation frequency from the modulated signal.

Such a configuration selectively extracts the modulation frequency component from the electrical signal, thereby reducing the effect of noise on the measuring system and improving the accuracy of detection of the heat flow by the thermoelectric conversion unit.

Of course, these aspects are not limiting.

Finally, while the various embodiments according to the present disclosure have been described above, the embodiments are only illustrative and are not intended to limit the scope of the invention. The novel embodiments can be carried out in other various forms, and various omissions, replacements, or changes can be made thereto without departing from the gist of the invention. The embodiments and modifications thereof are included in the scope and gist of the present invention, as well as included in the scope of the invention set forth in the claims and equivalents thereof.

1. A signal processing method in a measuring system, the measuring system including a thermoelectric conversion unit, implemented by circuitry, configured to convert a temperature gradient generated by heat exchange with an object to be measured into an electrical signal on the basis of the anomalous Nernst effect,
the signal processing method comprising:
a modulation step of generating a modulated signal by introducing a modulation including a predetermined modulation frequency into the electrical signal outputted from the thermoelectric conversion unit, the modulation frequency being a frequency different from a frequency band of the thermoelectric conversion unit; and
an extraction step of extracting a signal of a component of the modulation frequency from the modulated signal.

2. The signal processing method according to claim 1, wherein
the modulation step includes a magnetic field modulation step of introducing the modulation by applying an external magnetic field including the modulation frequency to the thermoelectric conversion unit.

3. The signal processing method according to claim 2, wherein
the magnetic field modulation step includes introducing the modulation by reversing a sign of an element based on the anomalous Nernst effect of a thermoelectric tensor of the thermoelectric conversion unit using the external magnetic field.

4. The signal processing method according to claim 2, wherein:
the thermoelectric conversion unit is formed as a thin film and is configured to be magnetized along an in-plane direction of the thin film, and
the magnetic field modulation step includes introducing the modulation by inducing the external magnetic field to the thermoelectric conversion unit along the in-plane direction.

5. The signal processing method according to claim 1, wherein
the modulation step further includes an electrical modulation step of performing the modulation by changing electrical characteristics of a circuit through which the electrical signal outputted from the thermoelectric conversion unit is transmitted such that the electrical characteristics are synchronized with the modulation frequency.

6. The signal processing method according to claim 5, wherein:
the circuit includes a switch capable of interrupting transmission of the electrical signal, and
the electrical modulation step includes performing the modulation by changing the switch between on and off on the basis of the modulation frequency.

7. A signal processing system in a measuring system, the measuring system including a thermoelectric conversion unit configured to convert a temperature gradient generated by heat exchange with an object to be measured into an electrical signal on the basis of the anomalous Nernst effect,
the signal processing system comprising:
a modulator configured to generate a modulated signal by introducing a modulation including a predetermined modulation frequency into the electrical signal outputted from the thermoelectric conversion unit, wherein the modulation frequency is a frequency outside a frequency band of the thermoelectric conversion unit; and
an extractor configured to extract a signal of a component of the modulation frequency from the modulated signal.

8. The signal processing system according to claim 7, further comprising
a magnetic field application unit, implemented by circuitry, configured to apply an external magnetic field including the modulation frequency to the thermoelectric conversion unit.

9. The signal processing system according to claim 8, wherein
the magnetic field application unit applies the external magnetic field to the thermoelectric conversion unit such that a sign of an element based on the anomalous Nernst effect of a thermoelectric tensor of the thermoelectric conversion unit is reversed by the external magnetic field.

10. The signal processing system according to claim 8, wherein:
the thermoelectric conversion unit is formed as a thin film and includes a magnetic domain configured to be magnetized along an in-plane direction of the thin film, and
the magnetic field application unit is disposed with respect to the thermoelectric conversion unit such that the external magnetic field applied to the thermoelectric conversion unit is induced along the in-plane direction.

11. The signal processing system according to claim 10, further comprising:
the thermoelectric conversion unit; and
an insulator having a first surface and a second surface opposite to the first surface in a thickness direction, wherein:
the thermoelectric conversion unit is stacked on the first surface,
the magnetic field application unit is disposed on the second surface so as to be electrically insulated from the thermoelectric conversion unit and comprises a first magnetic field generation element and a second magnetic field generation element, and
when the first magnetic field generation element and the second magnetic field generation element generate a magnetic field on the basis of an input signal having a phase difference corresponding to a positional relationship between the first magnetic field generation element and the second magnetic field generation element such that at least a portion of the external magnetic field is induced to the thermoelectric conversion unit along the in-plane direction of the thin film that is the thermoelectric conversion unit.

12. The signal processing system according to claim 7, wherein
the modulator further includes an electrical modulator configured to change the electrical signal outputted from the thermoelectric conversion unit such that electrical characteristics of a transmission circuit through which the electrical signal is transmitted from the thermoelectric conversion unit to the extractor are synchronized with the modulation frequency.

13. The signal processing system according to claim 12, wherein:
the transmission circuit includes a switch capable of interrupting transmission of the electrical signal, and
the electrical modulator is configured to perform the modulation by changing the switch between on and off on the basis of the modulation frequency.

14. The signal processing system according to claim 7, wherein
the extractor is configured to extract a signal of the modulation frequency from the modulated signal using a lock-in method based on a signal from an oscillator configured to output a signal of the modulation frequency.

15. A non-transitory computer-readable memory medium storing a signal processing program in a measuring system, the measuring system including a thermoelectric conversion unit configured to convert a temperature gradient generated by heat exchange with an object to be measured into an electrical signal on the basis of the anomalous Nernst effect,
the signal processing program being configured to cause at least one computer to perform:
a modulation step of generating a modulated signal by introducing a modulation including a predetermined modulation frequency into the electrical signal outputted from the thermoelectric conversion unit, the modulation frequency being a frequency different from a frequency band of the thermoelectric conversion unit; and
an extraction step of extracting a signal of a component of the modulation frequency from the modulated signal.
